(19) United States
(12) Patent Application Publication
(10) Pub. No.: US 2025/0176437 A1
(43) Pub. Date: May 29, 2025

(54) POWER FEEDING MEMBER AND VIBRATION DEVICE

(71) Applicant: Murata Manufacturing Co., Ltd., Nagaokakyo-shi (JP)

(72) Inventors: Yuuki ISHII, Nagaokakyo-shi (JP); Hitoshi SAKAGUCHI, Nagaokakyo-shi (JP); Noritaka KISHI, Nagaokakyo-shi (JP); Takahide NAKADOI, Nagaokakyo-shi (JP)

(21) Appl. No.: 19/039,223

(22) Filed: Jan. 28, 2025

Related U.S. Application Data
(63) Continuation of application No. PCT/JP2023/026079, filed on Jul. 14, 2023.

(30) Foreign Application Priority Data
Sep. 5, 2022 (JP) 2022-140983

(51) Int. Cl. H10N 30/87; H10N 30/20

(52) U.S. Cl. CPC H10N 30/875; H10N 30/20

(57) ABSTRACT

A power feeding member that includes: a joining member having a joining surface joinable to a piezoelectric element; at least one contact portion on the joining member and electrically connectable to an electrode of the piezoelectric element; and a wiring portion extending from the joining member, wherein when viewed along a first direction intersecting the joining surface, the at least one contact portion and a connection portion between the joining member and the wiring portion are located at offset positions.

### CROSS REFERENCE TO RELATED APPLICATIONS

The present application is a continuation of International application No. PCT/JP2023/026079, filed Jul. 14, 2023, which claims priority to Japanese Patent Application No. 2022-140983, filed Sep. 5, 2022, the entire contents of each of which are incorporated herein by reference.

### TECHNICAL FIELD

The present disclosure relates to a power feeding member and a vibration device including the power feeding member.

### BACKGROUND ART

Patent Document 1 discloses a droplet removal device having a function of securely and efficiently removing droplets, etc., adhering to a beam passing region of a dome-shaped drip-proof cover. In the droplet removal device of Patent Document 1, a piezoelectric element and a piezoelectric element controller are electrically connected to each other via a flexible board.

Patent Document 1: Japanese Unexamined Patent Application Publication No. 2017-170303

### SUMMARY OF THE DISCLOSURE

In the above droplet removal device, electrodes for applying a voltage to the piezoelectric element are disposed on an extension of the flexible board. Therefore, when a load is applied to the flexible board, the electrodes may peel off and the voltage application to the piezoelectric element may fail.

The present disclosure has an object to provide a power feeding member having a high reliability of joining to a piezoelectric element, and a vibration device including the power feeding member.

A power feeding member according to one aspect of the present disclosure includes: a joining member having a joining surface joinable to a piezoelectric element; at least one contact portion on the joining member and electrically connectable to an electrode of the piezoelectric element; and a wiring portion extending from the joining member.

When viewed along a first direction intersecting the joining surface, the at least one contact portion and a connection portion between the joining member and the wiring portion are located at offset positions.

A vibration device according to one aspect of the present disclosure includes: the power feeding member according to the above aspect; a piezoelectric element joined to the joining surface; a vibrator that intensifies vibration generated by the piezoelectric element; and a light-transmissive body connected to a first end of the vibrator in the first direction.

According to the present disclosure, it is possible to provide the power feeding member having a high reliability of joining to the piezoelectric element, and the vibration device including the power feeding member.

### BRIEF DESCRIPTION OF THE DRAWINGS

FIG. 1 is a perspective view illustrating a vibration device according to one embodiment of the present disclosure.

FIG. 2 is a cross-sectional view taken along the line II-II in FIG. 1.

FIG. 3 is a perspective view illustrating a power feeding member of the vibration device in FIG. 1.

FIG. 4 is a bottom view of the vibration device in FIG. 1.

FIG. 5 is a perspective view illustrating a first modification of the power feeding member in FIG. 3.

FIG. 6 is a bottom view of a vibration device including the power feeding member in FIG. 5.

FIG. 7 is a cross-sectional view taken along the line VII-VII in FIG. 6.

FIG. 8 is a side view illustrating a state in which a wiring portion is pulled in the vibration device in FIG. 1.

FIG. 9 is a bottom view of the vibration device in FIG. 8.

FIG. 10 is a graph illustrating a relationship between an angle and a stress acting on an adhesive layer.

FIG. 11 is a schematic cross-sectional view illustrating a first modification of a power feeding device in FIG. 5.

FIG. 12 is a schematic cross-sectional view illustrating a second modification of the power feeding device in FIG. 5.

FIG. 13 is a schematic cross-sectional view illustrating a third modification of the power feeding device in FIG. 5.

FIG. 14 is a schematic cross-sectional view illustrating a fourth modification of the power feeding device in FIG. 5.

FIG. 15 is a schematic plan view illustrating a fifth modification of the power feeding device in FIG. 5.

FIG. 16 is a schematic plan view illustrating a sixth modification of the power feeding device in FIG. 5.

FIG. 17 is a schematic plan view illustrating a seventh modification of the power feeding device in FIG. 5.

FIG. 18 is a schematic plan view illustrating an eighth modification of the power feeding device in FIG. 5.

FIG. 19 is a schematic plan view illustrating a ninth modification of the power feeding device in FIG. 5.

FIG. 20 is a diagram illustrating results of simulation of displacement amount distribution in the vibration device in FIG. 1.

FIG. 21 is a schematic cross-sectional view illustrating a first modification of the vibration device in FIG. 1.

FIG. 22 is a schematic plan view illustrating a tenth modification of the power feeding device in FIG. 3.

FIG. 23 is a schematic plan view illustrating an eleventh modification of the power feeding device in FIG. 5.

### DESCRIPTION OF THE PREFERRED EMBODIMENTS

A power feeding member according to a first aspect of the present disclosure includes: a joining member having a joining surface joinable to a piezoelectric element; at least one contact portion on the joining member and electrically connectable to an electrode of the piezoelectric element; and a wiring portion extending from the joining member, in which when viewed along a first direction intersecting the joining surface, the at least one contact portion and a connection portion between the joining member and the wiring portion are located at offset positions.

In the power feeding member according to the first aspect, when viewed along the first direction intersecting the joining surface, the at least one contact portion and the connection portion between the joining member and the wiring portion are located at offset positions so as not to overlap each other. Therefore, when a load is applied to the wiring portion, the load applied to the contact portion can be reduced. As a result, it is possible to realize the power feeding member having a high reliability of joining to the piezoelectric element.

In a power feeding member according to a second aspect of the present disclosure, in the power feeding member according to the first aspect, the joining member includes: a member body having the joining surface; and at least one protruding portion extending from the member body in a direction along the joining surface from the member body when viewed along the first direction, the at least one protruding portion being joinable to a vibrator, and the at least one contact portion is located on the protruding portion.

In the power feeding member according to the second aspect, the contact portion is located on the protruding portion. Therefore, when viewed along the first direction, the protruding portion and the connection portion between the member body and the wiring portion are located at offset positions. Thus, when a load is applied to the wiring portion, the load applied to the protruding portion can be reduced, and the reliability of joining of the protruding portion to the internal vibrator can be increased.

In a power feeding member according to a third aspect of the present disclosure, in the power feeding member according to the second aspect, the joining member includes a plurality of the protruding portions.

In the power feeding member according to the third aspect, the area of joining of the protruding portion to the internal vibrator is increased and therefore the reliability of joining of the protruding portion to the internal vibrator can further be increased.

In a power feeding member according to a fourth aspect of the present disclosure, in the power feeding member according to the second or third aspect, the at least one contact portion is positioned so as to be joined to the vibrator in a plane along the joining surface.

In the power feeding member according to the fourth aspect, the contact portion and the vibrator are joined to each other in the same plane. Therefore, the reliability of joining to the piezoelectric element is further improved.

In a power feeding member according to a fifth aspect of the present disclosure, in the power feeding member according to the first aspect, the joining member includes: a member body joinable to a vibrator; and at least one protruding portion extending from the member body in a direction along the joining surface from the member body when viewed along the first direction, the at least one protruding portion having the joining surface.

In the power feeding member according to the fifth aspect, it is possible to realize the power feeding member adaptable to vibration devices having various structures, thereby increasing the degree of freedom in terms of designing of the vibration device.

In a power feeding member according to a sixth aspect of the present disclosure, in the power feeding member according to any one of the first to fifth aspects, the wiring portion is positioned so as to extend from a part of the joining member having a smallest vibration.

In the power feeding member according to the sixth aspect, the wiring portion is positioned so as to extend from a part of the joining member having a smallest vibration. Therefore, the stress generated at the boundary portion between the wiring portion and the contact portion is reduced and the reliability of joining to the piezoelectric element is improved.

A vibration device according to a seventh aspect of the present disclosure includes: the power feeding member according to any one of the first to sixth aspects; a piezoelectric element joined to the joining surface; a vibrator that intensifies vibration generated by the piezoelectric element; and a light-transmissive body connected to a first end of the vibrator in the first direction.

In the vibration device according to the seventh aspect, the power feeding member can realize the vibration device having a high reliability.

One embodiment of the present disclosure is described below with reference to the accompanying drawings. The following description is substantially only illustrative and is not intended to limit the present disclosure, an object to which the present disclosure is applied, or the purpose of the present disclosure. The drawings are schematic drawings and the dimensional ratios etc. do not necessarily coincide with actual ones.

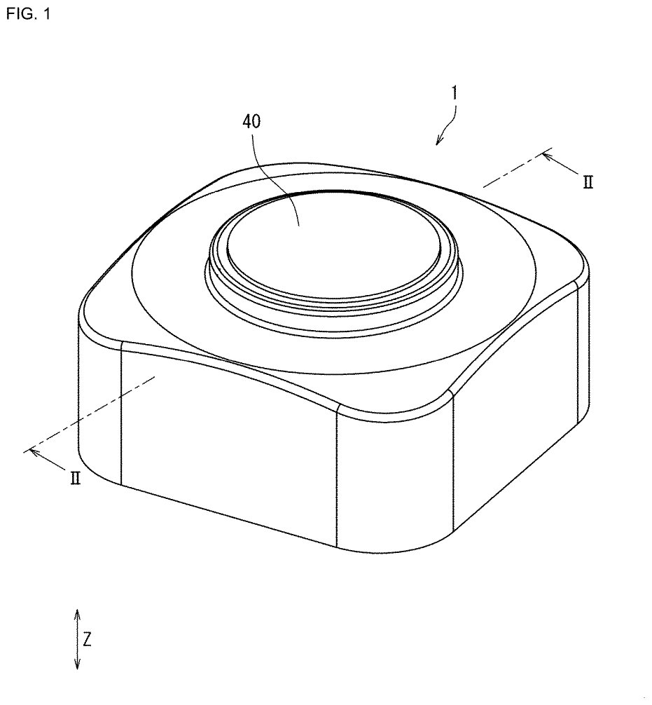

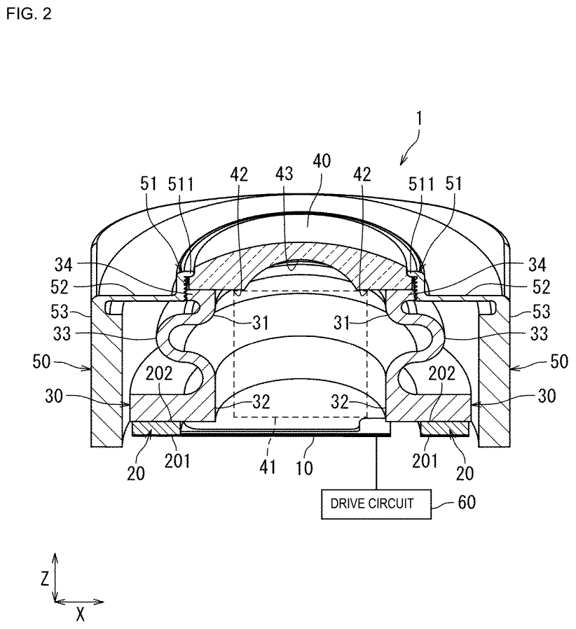

As illustrated in FIG. 1 and FIG. 2, a vibration device 1 according to the embodiment of the present disclosure includes a power feeding member 10, a piezoelectric element 20, an internal vibrator 30 (example of a vibrator), and a lens 40 (example of a light-transmissive body). In this embodiment, the vibration device 1 further includes a lens module 41 and an external vibrator 50.

As illustrated in FIG. 2, the power feeding member 10 is joined to the piezoelectric element 20 and can supply, for example, a drive signal from a drive circuit 60 to the piezoelectric element 20. The drive circuit 60 is formed by, for example, a printed board where on-board components are mounted. The piezoelectric element 20 supplied with the drive signal vibrates the internal vibrator 30 in a first direction (e.g., a Z direction) intersecting a joining surface 111 of the power feeding member 10 described later. When the piezoelectric element 20 vibrates, the lens 40 vibrates and foreign matter, such as water droplets, adhering to the lens 40 is removed.

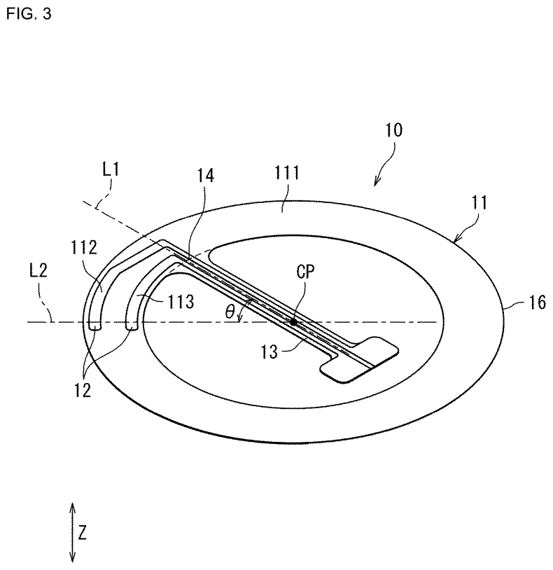

As illustrated in FIG. 3, the power feeding member 10 includes a joining member 11, a contact portion 12 provided to the joining member 11, and a wiring portion 13 extending from the joining member 11.

The joining member 11 is formed by, for example, a flexible printed board and includes a member body 16 having the joining surface 111. In this embodiment, the member body 16 has a substantially annular shape, but the shape is not limited thereto and any shape may be employed. The joining surface 111 is joinable to the piezoelectric element 20 and has a pair of band-shaped electrode patterns 112 and 113. The electrode patterns 112 and 113 are made of, for example, copper foil. The joining surface 111 has a large area of joining to the piezoelectric element 20. Therefore, the strength of joining to the piezoelectric element 20 is increased and the reliability of joining to the piezoelectric element 20 is improved.

The contact portion 12 is electrically connectable to electrodes of the piezoelectric element 20. In this embodiment, the power feeding member 10 includes two contact portions 12 and the ends of the electrode patterns 112 and 113 on one side serve as the contact portions 12. The ends of the electrode patterns 112 and 113 on the other side are located at the distal end of the wiring portion 13.

The wiring portion 13 is electrically connectable to the drive circuit 60 (see FIG. 2) and extends from the member body 16. In this embodiment, the wiring portion 13 is formed by a substantially T-shaped plate member extending along a radial direction from a radially inner lateral surface of the member body 16.

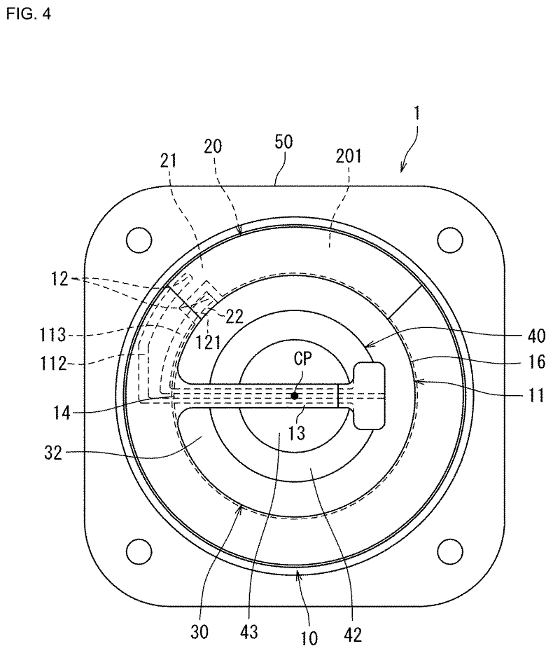

As illustrated in FIG. 3, when viewed along the first direction Z, the contact portion 12 and a connection portion 14 between the member body 16 of the joining member 11 and the wiring portion 13 are located at offset positions so as not to overlap each other. In this embodiment, the contact portion 12 is located at a circumferentially offset position from the connection portion 14, and an imaginary straight line L1 connecting a central point CP of the member body 16 and the connection portion 14 and an imaginary straight line L2 connecting the central point CP and the contact portion 12 have an angle θ larger than zero. In other words, the contact portion 12 is not located on the imaginary straight line L1. For example, the imaginary straight line L2 is a straight line passing through the central point CP and a point on the contact portion 12 (e.g., a point 121 in FIG. 4) that is closest to the imaginary straight line L1 in the circumferential direction about the central point CP.

The piezoelectric element 20 includes a piezoelectric body and electrodes. The piezoelectric element 20 is connected to a second portion 32 of the internal vibrator 30 described later with, for example, an adhesive. In this embodiment, the piezoelectric element 20 has a substantially annular shape when viewed along the first direction Z.

As illustrated in FIG. 4, a surface 201 (see FIG. 2) of the piezoelectric element 20 that faces the joining surface 111 has two electrodes 21 and 22 electrically independent of each other. The electrode 21 is in contact with the contact portion 12 formed by one end of the electrode pattern 112 located at a radially outer portion. The electrode 22 is in contact with the contact portion 12 formed by one end of the electrode pattern 113 located at a radially inner portion. A surface 202 (see FIG. 2) of the piezoelectric element 20 opposite in the first direction Z to the surface 201 that faces the joining surface 111 has an electrode (not illustrated) connected to the electrode 22. The electrode 22 on the surface 201 and the electrode on the surface 202 are connected to each other via an electrode (not illustrated) provided on the lateral surface of the piezoelectric element 20.

The piezoelectric body of the piezoelectric element 20 is made of piezoelectric ceramics such as barium titanate (BaTiO₃), lead zirconate titanate (PZT: PbTiO₃-PbZrO₃), lead titanate (PbTiO₃), lead metaniobate (PbNb₂O₆), bismuth titanate (Bi₄Ti₃O₁₂), or (K, Na)NbO₃, or piezoelectric monocrystals such as LiTaO₃ or LiNbO₃.

The electrode of the piezoelectric element 20 is, for example, a Ni electrode or an electrode including a metal thin film of Ag or Au. The electrode including the metal thin film is formed by, for example, sputtering, plating, or vapor deposition.

The internal vibrator 30 can vibrate the lens 40 by intensifying vibration from the piezoelectric element 20. The internal vibrator 30 is made of metal or ceramics such as stainless steel, aluminum, iron, titanium, or duralumin. The surface of the internal vibrator 30 may be subjected to surface treatment such as oxidation or anodizing to increase the close contact of the adhesive. When the surface of the internal vibrator 30 is, for example, black, a decrease in optical performance due to irregular light reflection can further be prevented.

In this embodiment, the internal vibrator 30 has, for example, a tubular body. As illustrated in FIG. 2, the internal vibrator 30 includes a first portion 31 in contact with the lens 40, a second portion 32 to which the piezoelectric element 20 is attached, and a third portion 33 connecting the first portion 31 and the second portion 32 and having a substantially S-shaped cross section. The first portion 31 has a cylindrical shape extending in an axial direction (i.e., the first direction Z) of the tubular body. The radially outer end of the first portion 31 serves as a fitting portion 34 connected to the external vibrator 50. The second portion 32 is a portion that vibrates along with vibration of the piezoelectric element 20, and has a larger thickness than the first portion 31 and the third portion 33. Thus, the vibration of the piezoelectric element 20 is transferred to the lens 40 more efficiently. The third portion 33 is a portion that supports the first portion 31 and transfers vibration of the second portion 32 to the first portion 31. The first portion 31, the second portion 32, and the third portion 33 may be formed integrally or separately. The maximum outside dimension (e.g., the maximum dimension in an X direction) of the third portion 33 is larger than the maximum outside dimension of the first portion 31, and the maximum outside dimension of the second portion 32 is larger than the maximum outside dimension of the third portion 33. Thus, the vibration of the piezoelectric element 20 can efficiently be transferred to the lens 40.

The lens 40 forms an optical imaging plane in cooperation with the lens module 41 disposed in series in the first direction Z. The lens 40 is made of, for example, glass and has a convex shape protruding in the first direction Z away from the power feeding member 10. The surface of the lens 40 is coated with, for example, a water-repellent film and an antireflective film (AR coating). As illustrated in FIG. 2, the surface of the lens 40 that faces the lens module 41 includes a flat portion 42 and a concave shape 43. The flat portion 42 is connected to the first portion 31 of the internal vibrator 30.

The lens module 41 includes a plurality of lenses and is located in an internal space of the internal vibrator 30. The lens module 41 is combined with the lens 40 to have optical performance with which images can be formed as an imaging element.

The external vibrator 50 can prevent vibration of the internal vibrator 30 from escaping to a member other than the lens 40, and efficiently transfer the vibration to the lens 40. The external vibrator 50 is provided so as to cover the entire internal vibrator 30, and protects the internal vibrator 30 and the lens module 41. The external vibrator 50 is made of a metal material such as stainless steel, aluminum, iron, titanium, or duralumin, or made of resin.

In this embodiment, the external vibrator 50 has, for example, a hollow quadrangular prism shape. As illustrated in FIG. 2, the external vibrator 50 includes a first connection portion 51, a second connection portion 52 connected to the first connection portion 51, and a fixed portion 53 connected to the second connection portion 52.

The first connection portion 51 together with the first portion 31 of the internal vibrator 30 can sandwich the radially outer end portion of the lens 40 in the first direction Z. Thus, the lens 40 is prevented from falling off the vibration device 1 when the lens 40 vibrates. In this embodiment, the first connection portion 51 is located at a radially outer portion from the first portion 31 of the internal vibrator 30 and the lens 40, and extends from the second connection portion 52 toward the outside of the vibration device 1 along the first direction Z. A protruding portion 511 that protrudes in the radial direction toward the lens 40 is provided at one end of the first connection portion 51 in the first direction Z. The radially outer end of the lens 40 is sandwiched in the first direction Z by the protruding portion 511 and the first portion 31 of the internal vibrator 30.

The second connection portion 52 absorbs vibration generated in the lens 40. In this embodiment, the second connection portion 52 extends annularly in a direction (e.g., the X direction) intersecting the first direction Z from the other end of the first connection portion 51 in the first direction Z. The thickness of the second connection portion 52 is smaller than the thickness of the fixed portion 53 and is, for example, equal to or larger than 0.2 mm and equal to or smaller than 1.0 mm. The thickness of the second connection portion 52 is 0.2 times to 1.5 times as large as the thickness of the third portion 33. With such a small thickness, the second connection portion 52 functions as a leaf spring.

Members such as a case that houses the imaging element and the lens module 41 are connected to the fixed portion 53. The fixed portion 53 has a node that reduces vibration to vibration that is one hundredth or less of a displacement amount of the lens 40 so as not to transfer the vibration to the connected members. The vibration of the fixed portion 53 can be reduced as the volume of the fixed portion 53 increases. In this embodiment, the fixed portion 53 has a quadrangular outer shape. With the quadrangular outer shape, the volume of the fixed portion 53 can be increased without increasing the size of the vibration device 1. For example, the volume is larger in the case of a cube of 25 mm×25 mm than in the case of a columnar shape having a diameter of 25 mm.

If the external vibrator 50 has a recess such as a groove, foreign matter such as water droplets or mud accumulates in the recess. Further, the accumulated foreign matter causes a decrease in vibration performance. In this embodiment, the corner portion of the external vibrator 50 is chamfered by, for example, R2.5 or more. Thus, metal fatigue due to ultrasonic vibration can be reduced and the recess formation in the external vibrator 50 can be suppressed. By chamfering the corner portion of the external vibrator 50, the corner portion of the external vibrator 50 can be prevented from being imaged even with a lens 40 having a wide angle of view of 180° or more.

With the power feeding member 10 and the vibration device 1 of the present disclosure, the following effects can be attained.

The power feeding member 10 includes the joining member 11 having the joining surface 111 joinable to the piezoelectric element 20, the contact portion 12 provided to the joining member 11 and electrically connectable to the electrode of the piezoelectric element 20, and the wiring portion 13 extending from the joining member 11. When viewed along the first direction intersecting the joining surface 111, the contact portion 12 and the connection portion 14 between the joining member 11 and the wiring portion 13 are located at offset positions. With this structure, when a load is applied to the wiring portion 13, the load applied to the contact portion 12 can be reduced. As a result, it is possible to realize the power feeding member 10 having a high reliability of joining to the piezoelectric element 20.

The vibration device 1 includes the power feeding member 10, the piezoelectric element 20 joined to the joining surface 111, the internal vibrator 30 that intensifies vibration generated by the piezoelectric element 20, and the lens 40 connected to one end of the internal vibrator 30 in the first direction. With this structure, it is possible to realize the vibration device 1 having a high reliability.

The power feeding member 10 and the vibration device 1 of the present disclosure may have the following structures.

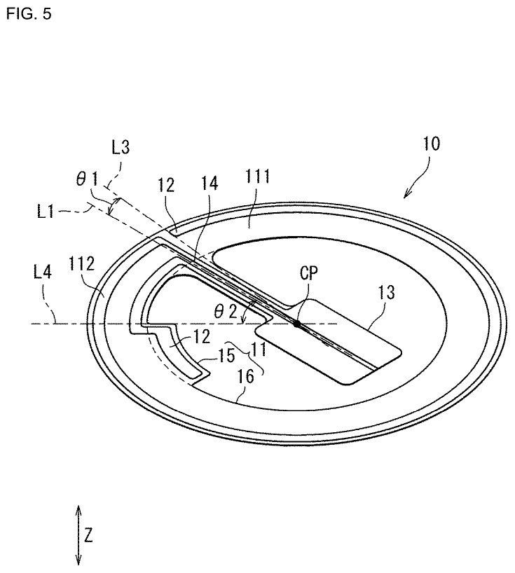

As illustrated in FIG. 5 to FIG. 7, the joining member 11 may include the member body 16 having the joining surface 111, and at least one protruding portion 15 provided to the member body 16. The protruding portion 15 extends in a direction along the joining surface 111 from the member body 16 when viewed along the first direction Z, and is joinable to the internal vibrator 30 that intensifies vibration generated by the piezoelectric element 20. In this embodiment, the protruding portion 15 has a substantially rectangular shape with its longitudinal direction corresponding to the circumferential direction about the central point CP, but the shape is not limited thereto and any shape may be employed.

In the power feeding member 10 in FIG. 5 to FIG. 7, the contact portion 12 is located on the protruding portion 15. Specifically, in the power feeding member 10 in FIG. 5 to FIG. 7, the contact portion 12 of the radially outer electrode pattern 112 is located on the joining surface 111 of the member body 16, and the contact portion 12 of the radially inner electrode pattern 113 is located on the protruding portion 15.

An imaginary straight line connecting the central point CP and the contact portion 12 of the radially outer electrode pattern 112 is represented by L3, and an imaginary straight line connecting the central point CP and the contact portion 12 of the radially inner electrode pattern 113 is represented by L4. The imaginary straight line L1 and the imaginary straight line L3 have an angle θ1 larger than zero, and the imaginary straight line L1 and the imaginary straight line L4 have an angle θ2 larger than zero. For example, the imaginary straight lines L3 and L4 are straight lines each passing through the central point CP and a point on the contact portion 12 (e.g., a point 122 or 123 in FIG. 6) that is closest to the imaginary straight line L1 in the circumferential direction about the central point CP. In this way, the protruding portion 15 and the connection portion 14 between the member body 16 and the wiring portion 13 are located at offset positions, specifically, located at different positions in the circumferential direction about the central point CP. Therefore, when a load is applied to the wiring portion 13, the load applied to the protruding portion 15 can be reduced, and the reliability of joining of the protruding portion 15 to the internal vibrator 30 can be increased.

In the power feeding member 10 in FIG. 5 to FIG. 7, the second portion 32 of the internal vibrator 30 includes a projecting portion 321 extending toward the protruding portion 15 of the power feeding member 10 as illustrated in FIG. 7. The projecting portion 321 has a substantially annular shape with a substantially quadrangular cross section, and a distal end surface 322 that faces the protruding portion 15 is located substantially flush with the surface 201 of the piezoelectric element 20 that faces the joining surface 111. The contact portion 12 and the internal vibrator 30 are joined to each other in a plane along the joining surface 111. Thus, power feeding to the surface of the piezoelectric element 20 that faces the internal vibrator 30 can be performed from the internal vibrator 30. As a result, a wiring layer that damps vibration need not be provided between the piezoelectric element 20 and the internal vibrator 30, and the vibration performance of the vibration device 1 including the power feeding member 10 can be improved. Since the contact portion 12 and the internal vibrator 30 are joined to each other in the same plane, the reliability of joining to the piezoelectric element 20 is further improved.

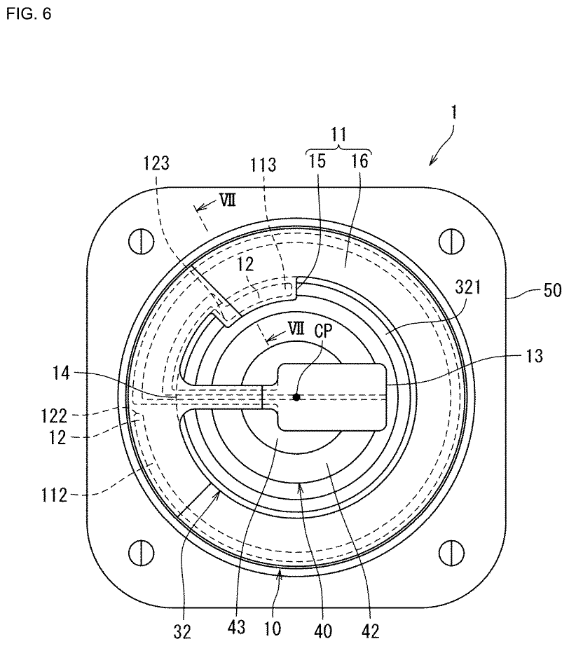

In the vibration device 1, it is assumed that the wiring portion 13 is pulled at F=1500 N/m in the first direction Z away from the lens 40 (see FIG. 8) and the power feeding member 10 at the connection portion 14 and the piezoelectric element 20 are joined to each other with an adhesive layer. In this case, the protruding portion 15 is provided at a position where the stress (maximum main stress) acting on the adhesive layer by pulling the wiring portion 13 is equal to or smaller than the strength of the adhesive layer. Therefore, the reliability of joining of the protruding portion 15 to the internal vibrator 30 can be increased. The adhesive layer may be made of any material.

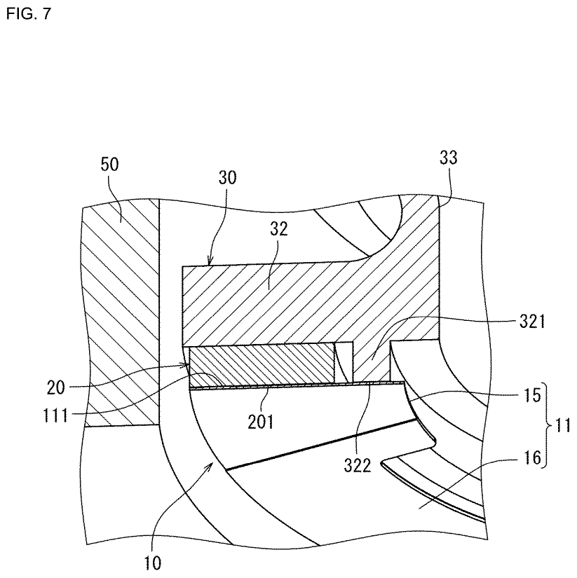

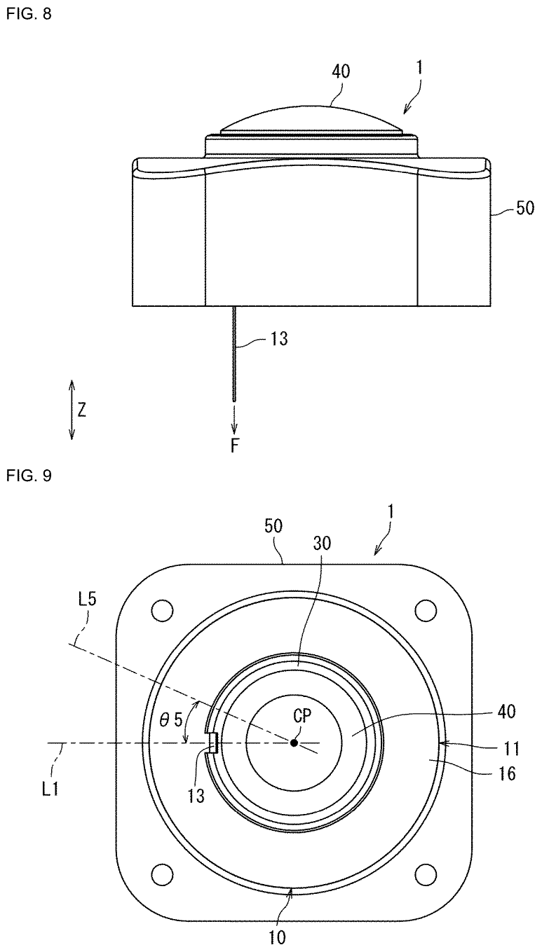

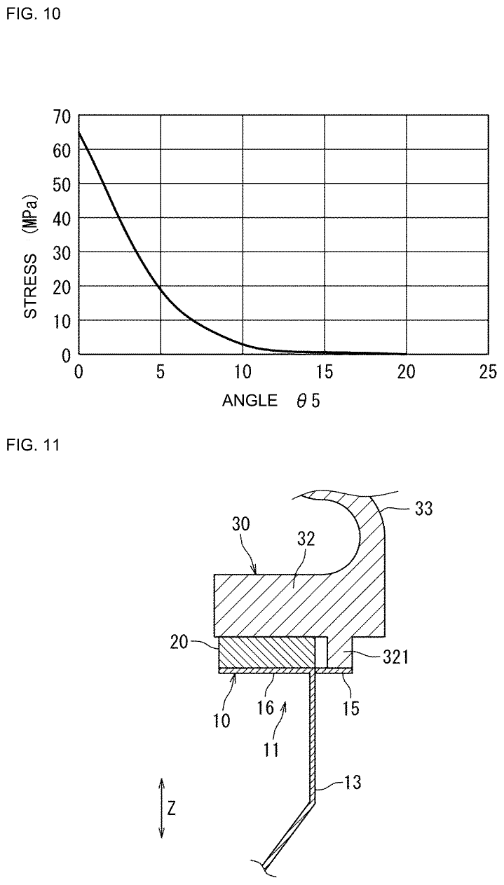

FIG. 10 illustrates a relationship between an angle θ5 (see FIG. 9) between the imaginary straight line L1 and any imaginary straight line L5 passing through the central point CP and the stress acting on the adhesive layer on the imaginary straight line L5. As illustrated in FIG. 10, when the strength of the adhesive layer is 40 MPa, a stress of 40 MPa or less acts on the adhesive layer at a position where the angle θ5 is equal to or larger than 2.5°. That is, when the strength of the adhesive layer is 40 MPa, the reliability of joining of the protruding portion 15 to the internal vibrator 30 is improved by providing the protruding portion 15 at a position away from the imaginary straight line L1 in the circumferential direction compared with the case of the imaginary straight line L5 at the angle θ5 of 2.5°.

The force F for pulling the wiring portion 13 is defined to be “1500 N/m” based on the value of a force applied to a handrail in Experiment No. 5 described in “Experiments to measure horizontal loads generated on handrail by various human actions, Journal of technology reports of Architectural Institute of Japan, Volume 16, No. 33, 649-654, June 2010.”

For example, the protruding height of the protruding portion 15 (i.e., the length of the protruding portion 15 along the radial direction from the radially inner portion of the member body 16) is set so that the protruding portion 15 overlaps the projecting portion 321 of the internal vibrator 30 but does not overlap the lens 40 when viewed along the first direction Z. Thus, it is possible to avoid interference between the protruding portion 15 and each of the lens 40 and the lens module 41.

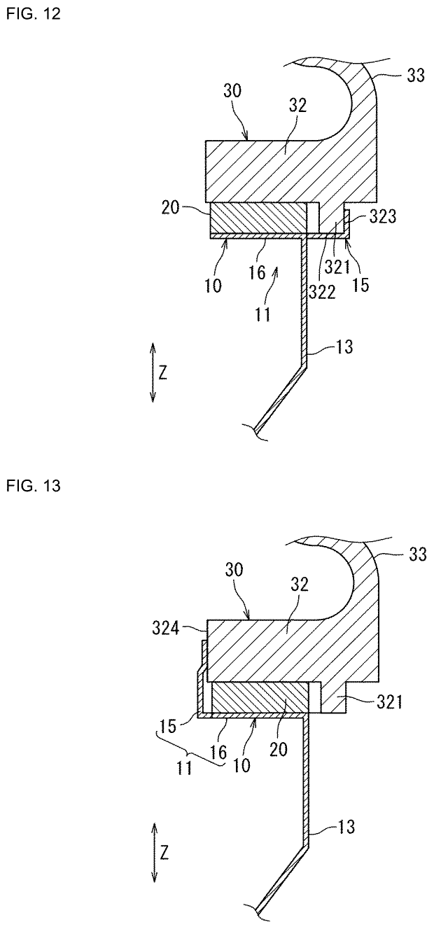

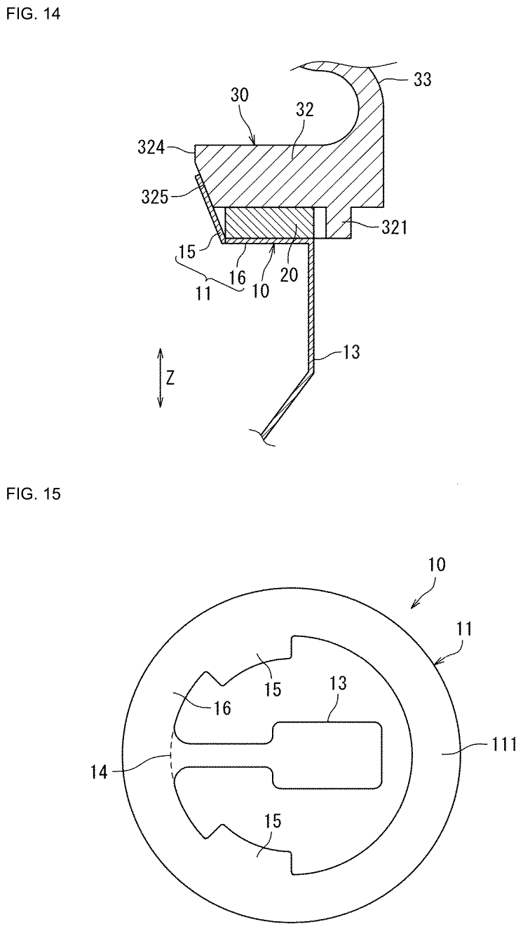

As illustrated in FIG. 11, the wiring portion 13 may be bent. It is possible to avoid interference between the wiring portion 13 and an internal component (e.g., the lens module 41) by positioning the wiring portion 13 near the piezoelectric element 20. As illustrated in FIG. 12, the protruding portion 15 may have a substantially L-shaped cross section so that the protruding portion 15 is joined to the distal end surface 322 and a lateral surface 323 of the projecting portion 321 of the internal vibrator 30. As illustrated in FIG. 13 and FIG. 14, the protruding portion 15 may be joinable to a lateral surface 324 of the second portion 32. In FIG. 14, the lateral surface 324 (lateral surface opposite to the lateral surface 323) of the internal vibrator 30 includes an inclined surface 325 and the protruding portion 15 is in surface contact with the inclined surface 325. As illustrated in FIG. 15, the protruding portion 15 is not limited to a single protruding portion and a plurality of protruding portions may be provided. In FIG. 15, the power feeding member 10 includes two protruding portions 15. With this structure, the area of joining of the protruding portion 15 to the internal vibrator 30 is increased and therefore the reliability of joining of the protruding portion 15 to the internal vibrator 30 is further improved. In FIG. 11 to FIG. 14, the members other than the power feeding member 10, the piezoelectric element 20, and the internal vibrator 30 are omitted. In FIG. 15, the electrode patterns on the joining surface 111 are omitted.

In the case where a plurality of protruding portions 15 is provided, the plurality of protruding portions 15 may be located at equal intervals in the circumferential direction or may be located symmetrically across the central point CP of the member body 16.

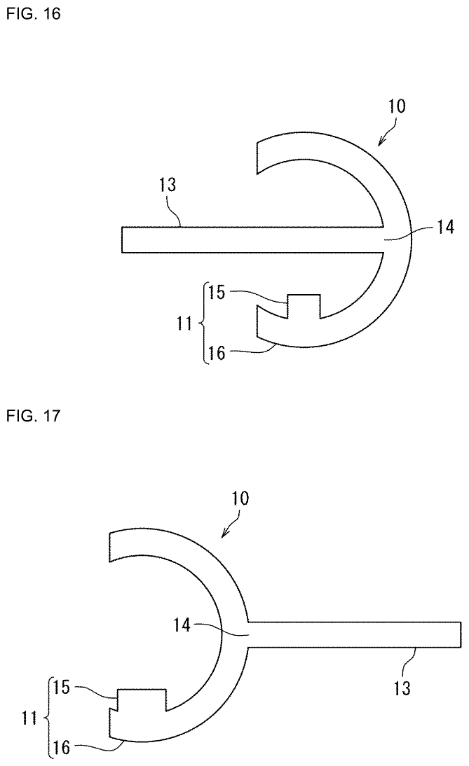

The shape of the member body 16 is not limited to the substantially annular shape and may be a substantial C-shape as illustrated in FIG. 16 to FIG. 18. With this structure, the wiring portion 13 can be elongated and, for example, inspection is facilitated. In this case, the power feeding member 10 may be structured as follows. In the following structure, as illustrated in FIG. 23, an angle between the imaginary straight line L1 and an imaginary straight line L6 is represented by θ6, an angle between the imaginary straight line L6 and an imaginary straight line L7 is represented by θ7, an angle between the imaginary straight line L1 and an imaginary straight line L8 is represented by θ8, and an angle between the imaginary straight line L8 and an imaginary straight line L9 is represented by θ9. The imaginary straight line L6 is an imaginary straight line passing through the central point CP and a part of the protruding portion 15 that is closest to the imaginary straight line L1 in the circumferential direction. The imaginary straight line L7 is an imaginary straight line passing through the central point CP and a part of the protruding portion 15 that is farthest from the imaginary straight line L1 in the circumferential direction. The imaginary straight line L8 is an imaginary straight line symmetrical to the imaginary straight line L6 across the imaginary straight line L1. The imaginary straight line L9 is an imaginary straight line symmetrical to the imaginary straight line L7 across the imaginary straight line L1. That is, the angle θ6 and the angle θ8 are equal to each other, and the angle θ7 and the angle θ9 are equal to each other.

$$\begin{matrix}Angle θ6 = angle θ8 \geq 2.5 ° \\ Angle θ7 = angle θ9 \geq 30 °\end{matrix}$$

When the angle θ6 and the angle θ8 are equal to or larger than 2.5°, the reliability of joining of the protruding portion 15 to the internal vibrator 30 can be improved as described above. When the angle θ7 and the angle θ9 are equal to or larger than 30°, the conduction between the projecting portion 15 and the internal vibrator 30 can be ensured more securely and a sufficient area of adhesion of the power feeding member 10 to the internal vibrator 30 can be ensured.

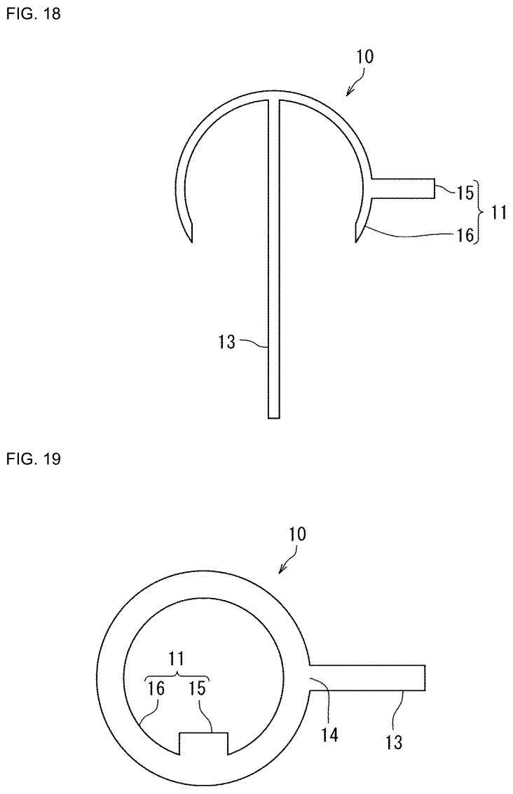

The wiring portion 13 is not limited to the case where the wiring portion 13 is provided at the radially inner portion from the member body 16 as illustrated in FIG. 16 and FIG. 18. For example, the wiring portion 13 may be provided at the radially outer portion from the member body 16 as illustrated in FIG. 17 and FIG. 19.

As illustrated in FIG. 18, the member body 16 may be joined to the internal vibrator 30 and the protruding portion 15 may have the joining surface 111. In the power feeding member 10 in FIG. 18, the member body 16 is joinable to the projecting portion 321 of the internal vibrator 30. Thus, it is possible to realize the power feeding member 10 adaptable to vibration devices 1 having various structures, thereby increasing the degree of freedom in terms of designing of the vibration device 1.

The wiring portion 13 may extend from a part of the joining member 11 with small vibration. With this structure, the stress generated at the boundary portion between the wiring portion 13 and the contact portion 12 is reduced and the reliability of joining to the piezoelectric element 20 is improved.

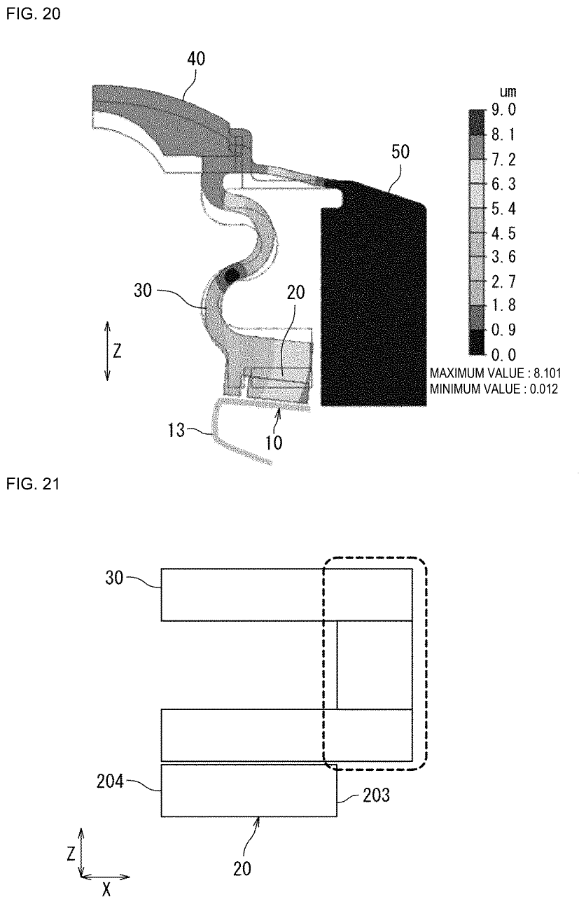

Results of simulation of displacement amount distribution in the vibration device 1 are described with reference to FIG. 20. In the simulation, piezoelectric analysis (resonance analysis) was performed on the vibration device 1 in FIG. 7 using Femtet (registered trademark) manufactured by Murata Software Co., Ltd. In the simulation, the lens 40 was made of a material corresponding to glass, the internal vibrator 30 and the external vibrator 50 were made of materials corresponding to stainless steel, and the piezoelectric element was made of a material corresponding to PZT (lead zirconate titanate). FIG. 20 demonstrates that, in the vibration device 1 in FIG. 7, the radially inner portion of the member body 16 is the part with small vibration (amplitude).

In the vibration device 1 including a substantially C-shaped internal vibrator 30 illustrated in FIG. 21, the internal vibrator 30 behaves as a tuning fork. Therefore, the vibration at an end portion 203 of the piezoelectric element 20 that is located near a part (indicated by the broken line) of the internal vibrator 30 that extends in the first direction Z is small and the vibration at an end portion 204 of the piezoelectric element 20 that is located away from the part indicated by the broken line in FIG. 21 in a direction (e.g., the X direction) intersecting the first direction Z is large. That is, in the vibration device including the internal vibrator 30 illustrated in FIG. 21, the reliability of joining to the piezoelectric element 20 can be improved by drawing the wiring portion 13 from a part of the joining member 11 that is located near the end portion 203 of the piezoelectric element 20.

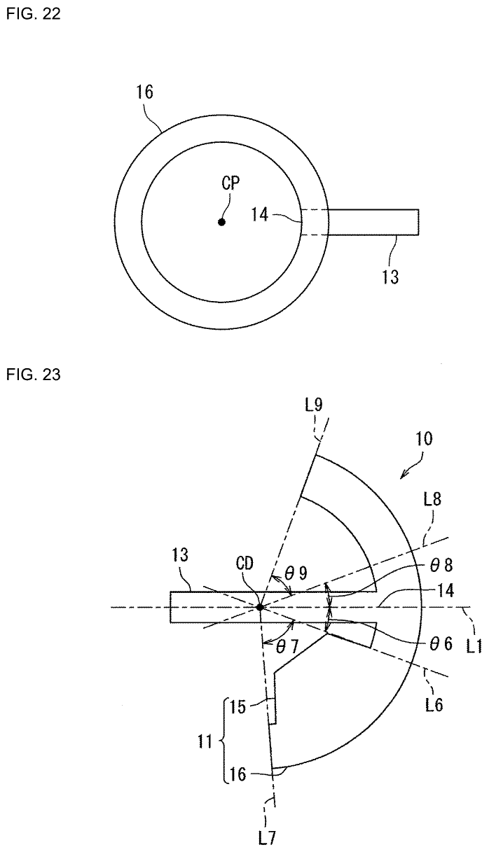

The direction in which the wiring portion 13 extends may be set to any direction. For example, as illustrated in FIG. 22, the wiring portion 13 may extend radially outward from the radially inner portion of the member body 16.

The electrode pattern is not limited to the electrode patterns 112 and 113 and the joining member 11 may have an electrode pattern having any structure with the contact portion 12 not located on the imaginary straight line L1.

The power feeding member 10 is applicable not only to the vibration device 1 of the embodiment but also to a vibration device having any other structure.

Any embodiments or modifications among the various embodiments or modifications may be combined as appropriate to attain their effects. The combination may be made between embodiments, between examples, or between an embodiment and an example, and features of different embodiments or examples may be combined.

Although the present disclosure has been described in each embodiment with some details, it is understood that the disclosure of the embodiment may be changed in the details of the structure, and the changes in the combination or order of the elements in the embodiment may be implemented without departing from the scope and spirit of the claimed disclosure.

### REFERENCE SIGNS LIST

1 vibration device
10 power feeding member
11 joining member
12 contact portion
13 wiring portion
14 connection portion
15 protruding portion
16 member body
20 piezoelectric element
21, 22 electrode
30 internal vibrator
31 first portion
32 second portion
33 third portion
34 fitting portion
40 lens
41 lens module
42 flat portion
43 concave shape
50 external vibrator
51 first connection portion
511 protruding portion
52 second connection portion
53 fixed portion
60 drive circuit
111 joining surface
112, 113 electrode pattern

1. A power feeding member comprising:
a joining member having a joining surface joinable to a piezoelectric element;
at least one contact portion on the joining member and electrically connectable to an electrode of the piezoelectric element; and
a wiring portion extending from the joining member, wherein
when viewed along a first direction intersecting the joining surface, the at least one contact portion and a connection portion between the joining member and the wiring portion are located at offset positions.

2. The power feeding member according to claim 1, wherein the joining member comprises:
a member body having the joining surface; and
at least one protruding portion extending from the member body in a direction along the joining surface from the member body when viewed along the first direction, the at least one protruding portion being joinable to a vibrator, and
the at least one contact portion is on the protruding portion.

3. The power feeding member according to claim 2, wherein the joining member includes a plurality of the protruding portions.

4. The power feeding member according to claim 2, wherein the at least one contact portion is positioned so as to be joined to the vibrator in a plane along the joining surface.

5. The power feeding member according to claim 1, wherein the joining member comprises:
a member body joinable to a vibrator; and
at least one protruding portion extending from the member body in a direction along the joining surface from the member body when viewed along the first direction, the at least one protruding portion having the joining surface.

6. The power feeding member according to claim 1, wherein the wiring portion is positioned so as to extend from a part of the joining member having a smallest vibration.

7. The power feeding member according to claim 1, wherein the joining member comprises an annular shaped member body.

8. The power feeding member according to claim 7, wherein the wiring portion extends radially inwardly from the annular shaped member body.

9. The power feeding member according to claim 7, wherein the wiring portion extends radially outwardly from the annular shaped member body.

10. A vibration device comprising:
the power feeding member according to claim 1;
a piezoelectric element joined to the joining surface;
a vibrator that intensifies vibration generated by the piezoelectric element; and
a light-transmissive body connected to a first end of the vibrator in the first direction.

11. The vibration device according to claim 10, wherein the joining member comprises:
a member body having the joining surface; and
at least one protruding portion extending from the member body in a direction along the joining surface from the member body when viewed along the first direction, the at least one protruding portion being joined to the vibrator, and
the at least one contact portion is on the protruding portion.

12. The vibration device according to claim 11, wherein the joining member includes a plurality of the protruding portions.

13. The vibration device according to claim 11, wherein the at least one contact portion is joined to the vibrator in a plane along the joining surface.

14. The vibration device according to claim 10, wherein the joining member comprises:
a member body joined to the vibrator; and
at least one protruding portion extending from the member body in a direction along the joining surface from the member body when viewed along the first direction, the at least one protruding portion having the joining surface.

15. The vibration device according to claim 10, wherein the wiring portion extends from a part of the joining member having a smallest vibration.

16. The vibration device according to claim 10, wherein the vibrator has a tubular body.

17. The vibration device according to claim 16, wherein the vibrator includes a first portion in contact with the light-transmissive body, a second portion attached to the piezoelectric element, and a third portion connecting the first portion and the second portion and having a substantially S-shaped cross section.

18. The vibration device according to claim 17, wherein the second portion is a portion that vibrates along with vibration of the piezoelectric element, and has a larger thickness than the first portion and the third portion.

19. The vibration device according to claim 17, wherein a maximum outside dimension of the third portion is larger than a maximum outside dimension of the first portion, and a maximum outside dimension of the second portion is larger than the maximum outside dimension of the third portion.

20. The vibration device according to claim 17, wherein the vibrator is a first vibrator and the vibration device further comprises a second vibrator covering an entirety of the first vibrator.
